(19) United States
(12) Patent Application Publication
(10) Pub. No.: US 2014/0262037 A1
(43) Pub. Date: Sep. 18, 2014

(54) TRANSPARENT YTTRIA COATED QUARTZ SHOWERHEAD

(71) Applicant: Applied Materials, Inc., Santa Clara, CA (US)

(72) Inventors: Ren-Guan DUAN, Fremont, CA (US); Juan Carlos ROCHA- ALVAREZ, San Carlos, CA (US)

(21) Appl. No.: 14/174,567

(22) Filed: Feb. 6, 2014

Related U.S. Application Data
(60) Provisional application No. 61/787,896, filed on Mar. 15, 2013.

(51) Int. Cl. H01J 37/32; B05B 1/18

(52) U.S. Cl. CPC H01J 37/3244; B05B 1/18
USPC 156/345.34; 427/161; 239/548

(57) ABSTRACT

Embodiments of the invention generally relate to a quartz showerhead having an aerosol-deposited yttria coating thereon. The yttria coating is sprayed on the quartz surface of the showerhead through a high pressure nozzle in a vacuum chamber. The yttria coating is transparent in the UV wavelength range, and allows the passage of UV light therethrough. The yttria coating erodes significantly slower than quartz in the presence of a cleaning gas, and thus extends the life of the quartz showerhead while facilitating the transmittance of UV light through the showerhead.

### CROSS-REFERENCE TO RELATED APPLICATIONS

This application claims benefit of U.S. Provisional Patent Application Ser. No. 61/787,896, filed Mar. 15, 2013, which is herein incorporated by reference.

### BACKGROUND OF THE INVENTION

1. Field of the Invention

Embodiments of the present invention generally relate to materials and coatings, and more specifically, to transparent materials resistant to corrosive plasmas of the kind used in the etching of semiconductor substrates.

2. Description of the Related Art

In ultraviolet (UV) process chambers, UV light is radiated from a UV source to a substrate located within the process chamber. A window and a showerhead are generally disposed within the UV light transmission path, and the window and showerhead generally should have a UV transmittance of greater than about 60 percent at 254 nm. Additionally, it is desirable that the transmittance is substantially constant from process cycle to process cycle.

Quartz windows and showerheads have been used previously in UV process chambers. While the quartz satisfies the UV transmittance requirement initially, quartz erodes quickly in the presence of cleaning plasmas, such as NF₃ plasma. The increased surface roughness of the quartz caused by the erosion significantly decreases the UV transmittance of the quartz. Thus, chamber performance is negatively influenced, and component lifetime is decreased.

Therefore, there is a need for a need for chamber components having increased erosion resistance.

### SUMMARY OF THE INVENTION

Embodiments of the invention generally relate to a quartz showerhead having an aerosol-deposited yttria coating thereon. The yttria coating is sprayed on the quartz surface of the showerhead through a high pressure nozzle in a vacuum chamber. The yttria coating is transparent in the UV wavelength range, and allows the passage of UV light therethrough. The yttria coating erodes significantly slower than quartz in the presence of a cleaning gas, and thus extends the life of the quartz showerhead while facilitating the transmittance of UV light through the showerhead.

In one embodiment, a method of processing a showerhead comprises depositing an yttria coating on quartz plate by aerosol deposition, and forming a plurality of openings through the quartz plate.

In another embodiment, a transparent showerhead comprises a quartz plate having a aerosol-deposited yttria coating disposed thereon. A plurality of passages are formed through the quartz plate and the yttria coating.

In another embodiment, a process chamber comprises one or more UV bulbs, a power source for generating a plasma, and a quartz plate having an aerosol-deposited yttria coating disposed thereon, wherein a plurality of passages are formed through the quartz plate and the yttria coating.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a plan view of a semiconductor processing system in which embodiments of the invention may be incorporated.

FIG. 2 is a view of a tandem processing chamber of the semiconductor processing system that is configured for UV curing.

FIG. 3 is a partial section view of the tandem processing chamber that has a lid assembly with two UV bulbs disposed respectively above two processing regions.

FIG. 4 is a schematic isometric cross-sectional view of a portion of one of the processing chambers without the lid assembly.

FIG. 5 is graph illustrating relative erosion rates of materials in the presence of fluorine plasma.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the invention generally relate to a quartz showerhead having an aerosol-deposited yttria coating thereon. The yttria coating is sprayed on the quartz surface of the showerhead through a high pressure nozzle in a vacuum chamber. The yttria coating is transparent in the UV wavelength range, and allows the passage of UV light therethrough. The yttria coating erodes significantly slower than quartz in the presence of a cleaning gas, and thus extends the life of the quartz showerhead while facilitating the transmittance of UV light through the showerhead.

FIG. 1 shows a plan view of a semiconductor processing system 100 which may use embodiments of the invention. The system 100 illustrates one embodiment of a Producer™ processing system, commercially available from Applied Materials, Inc., of Santa Clara, Calif. The processing system 100 is a self-contained system having the necessary processing utilities supported on a mainframe structure 101. The processing system 100 generally includes a front end staging area 102 where substrate cassettes 109 are supported and substrates are loaded into and unloaded from a loadlock chamber 112, a transfer chamber 111 housing a substrate handler 113, a series of tandem processing chambers 106 mounted on the transfer chamber 111 and a back end 138 which houses the support utilities needed for operation of the system 100, such as a gas panel 103, and a power distribution panel 105.

Each of the tandem processing chambers 106 includes two processing regions for processing the substrates. The two processing regions may share a common supply of gases, common pressure control, and common process gas exhaust/pumping system. Modular design of the system enables rapid conversion from any one configuration to any other. The arrangement and combination of chambers may be altered for purposes of performing specific process steps. Any of the tandem processing chambers 106 can include a lid according to aspects of the invention as described below that includes one or more ultraviolet (UV) lamps for use in a cure process of a low K material on the substrate and/or in a chamber clean process. In one embodiment, all three of the tandem processing chambers 106 have UV lamps and are configured as UV curing chambers to run in parallel for maximum throughput.

In an alternative embodiment where not all of the tandem processing chambers 106 are configured as UV curing chambers, the system 100 can be adapted with one or more of the tandem processing chambers having supporting chamber hardware known to accommodate various other known processes such as chemical vapor deposition (CVD), physical vapor deposition (PVD), etch, and the like. For example, the system 100 can be configured with one of the tandem processing chambers 106 as a CVD chamber for depositing materials, such as a low dielectric constant (K) film, on the substrates. Such a configuration can maximize research and development fabrication utilization and, if desired, eliminate exposure of as-deposited films to atmosphere.

A controller 140, including a central processing unit (CPU) 144, a memory 142, and support circuits 146, is coupled to the various components of the semiconductor processing system 100 to facilitate control of the processes of the present invention. The memory 142 can be any computer-readable medium, such as random access memory (RAM), read only memory (ROM), floppy disk, hard disk, or any other form of digital storage, local or remote to the semiconductor processing system 100 or CPU 144. The support circuits 146 are coupled to the CPU 144 for supporting the CPU in a conventional manner. These circuits include cache, power supplies, clock circuits, input/output circuitry and subsystems, and the like. A software routine or a series of program instructions stored in the memory 142, when executed by the CPU 144, causes the UV curing tandem processing chambers 106 to perform processes of the present invention.

FIG. 2 illustrates one of the tandem processing chambers 106 of the semiconductor processing system 100 that is configured for UV curing. The tandem processing chamber 106 includes a body 200 and a lid 202 that can be hinged to the body 200. The chamber body 200 may be made from aluminum. Coupled to the lid 202 are two housings 204 that are each coupled to inlets 206 along with outlets 208 for passing cooling air through an interior of the housings 204. The cooling air can be at room temperature or approximately twenty-two degrees Celsius. A central pressurized air source 210 provides a sufficient flow rate of air to the inlets 206 to insure proper operation of any UV lamp bulbs and/or power sources 214 for the bulbs associated with the tandem processing chamber 106. The outlets 208 receive exhaust air from the housings 204, which is collected by a common exhaust system 212 that can include a scrubber to remove ozone potentially generated by the UV bulbs, depending on bulb selection. Ozone management issues can be avoided by cooling the lamps with oxygen-free cooling gas (e.g., nitrogen, argon or helium).

FIG. 3 shows a partial section view of the tandem processing chamber 106 with the lid 202, the housings 204 and the power sources 214. Each of the housings 204 cover a respective one of two UV lamp bulbs 302 disposed respectively above two processing regions 300 defined within the body 200. Each of the processing regions 300 includes a heating substrate support, such as substrate support 306, for supporting a substrate 308 within the processing regions 300. The substrate supports 306 can be made from ceramic or metal such as aluminum. Preferably, the substrate supports 306 couple to stems 310 that extend through a bottom of the body 200 and are operated by drive systems 312 to move the substrate supports 306 in the processing regions 300 toward and away from the UV lamp bulbs 302. The drive systems 312 can also rotate and/or translate the substrate supports 306 during curing to further enhance uniformity of substrate illumination. Adjustable positioning of the substrate supports 306 enables control of volatile cure by-product and purge and clean gas flow patterns and residence times in addition to potential fine tuning of incident UV irradiance levels on the substrate 308 depending on the nature of the light delivery system design considerations such as focal length.

In general, any UV source such as mercury microwave arc lamps, pulsed xenon flash lamps or high-efficiency UV light emitting diode arrays may be used. The UV lamp bulbs 302 are sealed plasma bulbs filled with one or more gases such as xenon (Xe) or mercury (Hg) for excitation by the power sources 214. Preferably, the power sources 214 are microwave generators that can include one or more magnetrons (not shown) and one or more transformers (not shown) to energize filaments of the magnetrons. In one embodiment having kilowatt microwave (MW) power sources, each of the housings 204 includes an aperture 215 adjacent the power sources 214 to receive up to about 6000 W of microwave power from the power sources 214 to subsequently generate up to about 100 W of UV light from each of the bulbs 302. In another embodiment, the UV lamp bulbs 302 can include an electrode or filament therein such that the power sources 214 represent circuitry and/or current supplies, such as direct current (DC) or pulsed DC, to the electrode.

For some embodiments, the power sources 214 can include radio frequency (RF) energy sources that are capable of excitation of the gases within the UV lamp bulbs 302. The configuration of the RF excitation in the bulb can be capacitive or inductive. An inductively coupled plasma (ICP) bulb can be used to efficiently increase bulb brilliancy by generation of denser plasma than with the capacitively coupled discharge. In addition, the ICP lamp eliminates degradation in UV output due to electrode degradation resulting in a longer-life bulb for enhanced system productivity. Benefits of the power sources 214 being RF energy sources include an increase in efficiency.

Preferably, the bulbs 302 emit light across a broad band of wavelengths from 170 nm to 400 nm. In one embodiment of the invention, the bulbs 302 emit light at wavelengths from 185 nm to 255 nm. The gases selected for use within the bulbs 302 can determine the wavelengths emitted. UV light emitted from the UV lamp bulbs 302 enters the processing regions 300 by passing through windows 314 disposed in apertures in the lid 202. The windows 314 preferably are made of an OH free synthetic quartz glass and have sufficient thickness to maintain vacuum without cracking. Further, the windows 314 are preferably fused silica that transmits UV light down to approximately 150 nm. Since the lid 202 seals to the body 200 and the windows 314 are sealed to the lid 202, the processing regions 300 provide volumes capable of maintaining pressures from approximately 1 Torr to approximately 650 Torr. Processing or cleaning gases enter the processing regions 300 via a respective one of two inlet passages 316. The processing or cleaning gases then exit the processing regions 300 via a common outlet port 318. Additionally, the cooling air supplied to the interior of the housings 204 circulates past the bulbs 302, but is isolated from the processing regions 300 by the windows 314.

The housings 204 may include an interior parabolic surface defined by a cast quartz lining 304 coated with a dichroic film. The quartz linings 304 reflect UV light emitted from the UV lamp bulbs 302 and are shaped to suit the cure processes as well as the chamber clean processes based on the pattern of UV light directed by the quartz linings 304 into the processing regions 300. The quartz linings 304 may be adjusted to better suit each process or task by moving and changing the shape of the interior parabolic surface. Additionally, the quartz linings 304 may transmit infrared light and reflect ultraviolet light emitted by the bulbs 302 due to the dichroic film. The dichroic film usually constitutes a periodic multilayer film composed of diverse dielectric materials having alternating high and low refractive index. Since the coating is non-metallic, microwave radiation from the power sources 214 that is downwardly incident on the backside of the cast quartz linings 304 does not significantly interact with, or get absorbed by, the modulated layers and is readily transmitted for ionizing the gas in the bulbs 302.

Substrates are brought into the processing region 300, to perform a post-treatment cure of dielectric films deposited on the substrate 308. The films may be low-k dielectric films having porogens including, for example, a silicon backbone structure and carbon within the film. The silicon backbone structure and carbon within the film is sometimes referred to as porogen. After UV exposure, the carbon bonds break and the carbon outgases from the film, leaving a silicon backbone, and increasing porosity which decreases the k value and reduces the current carrying capacity of the film.

In conventional systems, a cross-flow non-uniform gas flow profile purges the chamber during curing and outgassing of the substrate. A purge gas flows from one side of the chamber to the opposite side, in-between the substrate and the window, so that any residue escaping the film is carried away before it can condense on the window or anywhere else in the chamber. Due to the uncontrolled non-uniformity of the flow profile, the substrate processing would also be non-uniform and result in a temperature gradient across the substrate. However, the resultant non-uniformity of the films in the 45 nm range may be acceptable, but will not be in the next generation of 20-28 nm films.

FIG. 4 shows a schematic isometric cross-sectional view of a portion of one of the processing chambers 400. A portion of processing chamber 400 shows various hardware designs to enable control of the gas flow profile throughout the processing chamber. A window assembly is positioned within the processing chamber 400 to hold a UV vacuum window 412. The window assembly includes a vacuum window clamp 410 that rests on a portion of the body 200 and supports a vacuum window 412 through which UV light may pass from the UV lamps 302, which is part of the lid assembly above the body 200. The vacuum window 412 is positioned between the UV radiation source, such as UV lamps 302, and the substrate support 306. The UV radiation source 302 is spaced apart from the substrate support 306 and configured to generate and transmit ultraviolet radiation to a substrate 308 positioned on the substrate support 306.

A transparent showerhead 414 is positioned within the processing region 300 and between the vacuum window 412 and the substrate support, such as substrate support 306. The transparent showerhead defines an upper processing region 320 between the vacuum window 412 and transparent showerhead 414 and further defines a lower processing region 322 between the transparent showerhead 414 and a substrate support. The transparent showerhead 414 also has one or more passages 416 between the upper and lower processing regions 320, 322.

The transparent showerhead 414 forms a second window through which UV light may pass to reach the substrate 308. As a second window, the showerhead 414 needs to be transparent to the wavelengths of light desired for curing the film on the substrate 308. The transparent showerhead may be formed of various transparent materials such as quartz. To facilitate increased erosion resistance of the showerhead 414, the showerhead includes a protective coating 490 formed of yttria disposed thereon. The passages 416 may be formed by drilling holes through a quartz piece having the coating 490 disposed thereon. The size and density of the passages 416 may be uniform or non-uniform to effectuate the desired flow characteristics across the substrate surface. The passages 416 may have either a uniform flow profile where the flow per radial area across the substrate 308 is uniform or the gas flow can be preferential to the center or edge of the substrate 308, i.e. the gas flow may have a preferential flow profile.

The protective coating 490 may be deposited on the transparent showerhead 414 by aerosol deposition. In one example, yttria particles having a size within a range of about 10 nanometers to about 5 micrometers are mixed with water or another fluid to form a slurry, and then ejected from a nozzle using a carrier gas such as air, nitrogen, or argon to form an aerosol. The yttria from the aerosol is deposited on a quartz plate from which the transparent showerhead 414 is formed. The protective coating 290 may be deposited to a thickness within a range of about 1 micrometer to about 10 micrometers. After deposition of the protective coating 290 on the quartz plate, passages 416 are formed therethrough to form the transparent showerhead 414. In one example, an yttria coating having a thickness of 2 micrometers is deposited by aerosol deposition on a quartz plate, and passages are formed therethrough resulting in a showerhead. The showerhead has a transmittance greater than 60 percent for UV light at a wavelength of 254 nanometers.

FIG. 5 is graph illustrating relative erosion rates of materials in the presence of fluorine plasma. The erosion rates are normalized for yttria. The erosion rate of yttrium aluminum garnet (YAG) is 2.34 times that of yttria. The erosion rate of Al₂O₃ is 5.11 times that if yttria. The erosion rate of aluminum nitride (AlN) is 6.68 that yttria. The erosion rate of silicon carbide (SiC) is 33.62 times that of yttria. The erosion rate of quartz is 70.43 times that of yttria. Thus, by coating a quartz showerhead with yttria, the erosion rate of the showerhead is significantly reduced, while allowing the showerhead to maintain sufficient transparency to UV light within a desired wavelength range.

Benefits of the invention generally include showerheads having increased resistance to plasma erosion, and a transmittance greater than 60 percent for UV light at a wavelength of 254 nanometers. The increased resistance to plasma erosion prolongs the useful life of the showerhead, and reduces contamination within a process chamber housing the showerhead.

While the foregoing is directed to embodiments of the present invention, other and further embodiments of the invention may be devised without departing from the basic scope thereof, and the scope thereof is determined by the claims that follow.

We claim:

1. A method of processing a showerhead, comprising:
depositing an yttria coating on quartz plate by aerosol deposition; and
forming a plurality of openings through the quartz plate.

2. The method of claim 1, wherein the aerosol deposition comprises mixing yttria particles with water to form a slurry, and ejecting the slurry from the nozzle with a carrier gas.

3. The method of claim 2, wherein the carrier gas comprises one or more of air, nitrogen, or argon.

4. The method of claim 2, wherein the yttria particles have a size within a range of about 10 nanometers to about 5 micrometers.

5. The method of claim 1, wherein the yttria coating is deposited to a thickness of about 1 micrometer to about 10 micrometers.

6. The method of claim 5, wherein the yttria coating is deposited to a thickness of about 2 micrometers.

7. The method of claim 1, wherein the plurality of openings are formed through the quartz plate after depositing the yttria coating.

8. The method of claim 1, wherein the quartz plate having the yttria coating thereon has a transmittance greater than 60 percent for UV light at a wavelength of 254 nanometers.

9. A transparent showerhead, comprising:
a quartz plate having an aerosol-deposited yttria coating disposed thereon, wherein a plurality of passages are formed through the quartz plate and the yttria coating.

10. The transparent showerhead of claim 9, wherein the yttria coating is deposited to a thickness of about 1 micrometer to about 10 micrometers.

11. The transparent showerhead of claim 10, wherein the yttria coating is deposited to a thickness of about 2 micrometers.

12. The transparent showerhead of claim 9, wherein the quartz plate having the yttria coating thereon has a transmittance greater than 60 percent for UV light at a wavelength of 254 nanometers.

13. A process chamber, comprising:
one or more UV bulbs,
a power source for generating a plasma; and
a quartz plate having an aerosol-deposited yttria coating disposed thereon, wherein a plurality of passages are formed through the quartz plate and the yttria coating.

14. The process chamber of claim 13, wherein the quartz plate having the yttria coating thereon has a transmittance greater than 60 percent for UV light at a wavelength of 254 nanometers.

15. The process chamber of claim 13, wherein the yttria coating is deposited to a thickness of about 1 micrometer to about 10 micrometers.
